(19) United States
(12) Patent Application Publication
(10) Pub. No.: US 2024/0347498 A1
(43) Pub. Date: Oct. 17, 2024

(54) MEMORY DEVICES, AND SEMICONDUCTOR PACKAGES INCLUDING THE SAME

(71) Applicant: SAMSUNG ELECTRONICS CO., LTD., Suwon-si (KR)

(72) Inventors: Daesik MOON, Suwon-si (KR); Sangwook PARK, Suwon-si (KR)

(21) Appl. No.: 18/409,465

(22) Filed: Jan. 10, 2024

(30) Foreign Application Priority Data
Apr. 12, 2023 (KR) 10-2023-0047874

(51) Int. Cl. H01L 23/00; H01L 23/498; H10B 80/00

(52) U.S. Cl. CPC H01L 24/48; H01L 23/49827; H01L 24/49; H10B 80/00; H01L 24/32; H01L 24/73; H01L 2224/32105; H01L 2224/32148; H01L 2224/48229; H01L 2224/49175; H01L 2224/73265; H01L 2924/1436; H01L 2924/1438

(57) ABSTRACT

A memory device comprising: a semiconductor substrate; a plurality of wire bonding pads on the semiconductor substrate and arranged in a first direction; a plurality of signal redistribution patterns connecting first wire bonding pads among the plurality of wire bonding pads to a plurality of signal via pads, respectively, wherein the plurality of signal redistribution patterns are on a first side with respect to the plurality of wire bonding pads in a second direction that is perpendicular to the first direction; and a plurality of power redistribution patterns connected to second wire bonding pads among the plurality of wire bonding pads, respectively, wherein the plurality of power redistribution patterns are on a second side with respect to the plurality of wire bonding pads in the second direction, wherein the first and second directions are parallel with an upper surface of the semiconductor substrate.

### CROSS-REFERENCE TO RELATED APPLICATION(S)

This application claims the benefit under 35 USC 119(a) of Korean Patent Application No. 10-2023-0047874 filed on Apr. 12, 2023 in the Korean Intellectual Property Office, the entire disclosure of which is incorporated herein by reference for all purposes.

### BACKGROUND

The present inventive concept relates to memory devices and semiconductor packages including the same.

Memory devices may include pads exposed externally for electrical connection (e.g., connection) with other external devices, and the pads may be electrically connected (e.g., connected) to other external devices by wire bonding or the like. The memory devices may receive power required for operation through the pads or exchange signals with other external devices. The pads are electrically connected (e.g., connected) to an input/output circuit transmitting/receiving a signal or receiving a power supply voltage. To design memory devices efficiently, the input/output circuits may be collectively disposed in a predetermined area. However, when the input/output circuits are collectively disposed, signal integrity and power supply integrity may be deteriorated due to redistribution patterns for the pads and input/output circuits.

### SUMMARY

Example embodiments of the present inventive concepts may separate and dispose signal redistribution patterns and power redistribution patterns based on wire bonding pads connected to other external devices through wires, thereby improving signal integrity and power integrity.

According to example embodiments, a memory device comprising: a semiconductor substrate; a plurality of wire bonding pads on the semiconductor substrate and arranged in a first direction; a plurality of signal redistribution patterns connecting first wire bonding pads among the plurality of wire bonding pads to a plurality of signal via pads, respectively, wherein the plurality of signal redistribution patterns are on a first side with respect to the plurality of wire bonding pads in a second direction that is perpendicular to the first direction; and a plurality of power redistribution patterns connected to second wire bonding pads among the plurality of wire bonding pads, respectively, wherein the plurality of power redistribution patterns are on a second side with respect to the plurality of wire bonding pads in the second direction, wherein the first and second directions are parallel with an upper surface of the semiconductor substrate.

According to example embodiments, a memory device comprising: a semiconductor substrate having a first edge and a second edge that are parallel to each other, wherein the first edge and the second edge extend in a first direction that is parallel to an upper surface of the semiconductor substrate; a plurality of wire bonding pads on the semiconductor substrate and arranged in the first direction; and a plurality of signal via pads between the first edge and the plurality of wire bonding pads, wherein a distance between the plurality of wire bonding pads and the first edge is shorter than a distance between the plurality of wire bonding pads and the second edge.

According to example embodiments, a semiconductor package comprising: a memory device; a package substrate positioned below the memory device; and a plurality of wires connecting the memory device and the package substrate, wherein the memory device includes: a semiconductor substrate; a plurality of wire bonding pads on the semiconductor substrate and arranged in a first direction that is parallel to an upper surface of the semiconductor substrate; a plurality of signal redistribution patterns connecting first wire bonding pads among the plurality of wire bonding pads to a plurality of signal via pads, wherein the plurality of signal redistribution patterns are on one side with respect to the plurality of wire bonding pads in a second direction that is perpendicular to the first direction and parallel to the upper surface of the semiconductor substrate; and a plurality of power redistribution patterns connected to second wire bonding pads among the plurality of wire bonding pads, wherein the plurality of power redistribution patterns are on the other side with respect to the plurality of wire bonding pads in the second direction, and the plurality of wires are connected to the plurality of wire bonding pads, wherein at least one of the plurality of wires overlaps at least one of the plurality of signal redistribution patterns.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a semiconductor package according to some example embodiments;

FIG. 2 is a diagram illustrating a semiconductor package according to some example embodiments;

FIG. 3 is a diagram illustrating a semiconductor package according to some example embodiments;

FIG. 4 is a plan view illustrating a semiconductor package according to some example embodiments;

FIGS. 5A and 5B are plan views illustrating a semiconductor package according to some example embodiments;

FIG. 6 is a plan view illustrating a memory device according to some example embodiments;

FIG. 7 is a cross-sectional view of the memory device according to the example embodiments illustrated in FIG. 6, in an I-I′ direction;

FIG. 8 is a cross-sectional view of the memory device according to the example embodiments illustrated in FIG. 6, in a II-II′ direction;

FIG. 9 is a plan view illustrating a memory device according to some example embodiments;

FIG. 10 is a plan view illustrating a memory device according to some example embodiments;

FIG. 11 is a plan view illustrating a memory device according to some example embodiments;

FIG. 12 is a plan view illustrating a memory device according to some example embodiments; and

FIG. 13 is a simplified block diagram of a mobile system including a memory device according to some example embodiments.

### DETAILED DESCRIPTION

Hereinafter, example embodiments will be described with reference to the accompanying drawings.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the idea and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer, or section from another element, component, region, layer, or section. Thus, a first element, component, region, layer or section described under could be termed a second element, component, region, layer or section, without departing from the idea and scope of the present disclosure.

In addition, it will also be understood that when a first element or layer is referred to as being present “on”, “on a top” “beneath”, “below”, “under”, or the like a second element or layer, the first element may be disposed directly on, on a top, beneath, below, under, or the like the second element or may be disposed indirectly on, on a top, beneath, below, under, or the like the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, “directly on”, or the like another element, there are no intervening elements present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

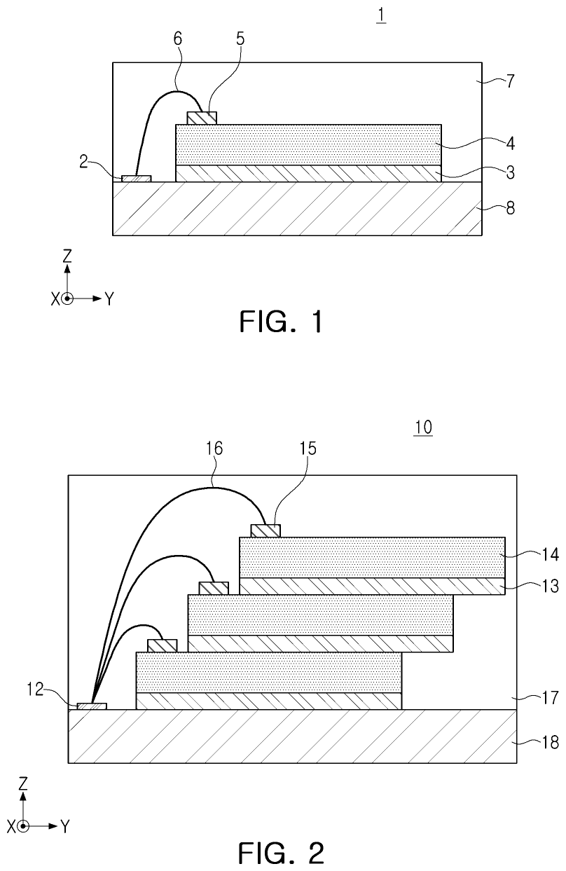

FIG. 1 is a diagram illustrating a semiconductor package according to some example embodiments.

Referring to FIG. 1, a semiconductor package 1 according to some example embodiments may include a memory device 4, a molding portion 7, and a package substrate 8. The memory device 4 may be disposed on an upper surface of the package substrate 8. In some embodiment, the memory device 4 may be attached on the upper surface of the package substrate 8 by an adhesive layer 3. For example, the adhesive layer 3 may be disposed between the memory device 4 and the package substrate 8. The molding portion 7 may be formed on (e.g., may cover) the memory device 4 and (e.g., the upper surface of) the package substrate 8.

The package substrate 8 may include a plurality of connection pads 2, and the plurality of connection pads 2 may be disposed (e.g., arranged) in a first direction (e.g., X-axis direction in FIG. 1). In some embodiments, the plurality of connection pads 2 may be disposed on the upper surface of the package substrate 8. The plurality of connection pads 2 may be connected to a plurality of wire bonding pads 5 formed on the memory device 4 by a plurality of wires 6. The memory device 4 may transmit and receive signals to and from the package substrate 8 through some (e.g., portions) of the plurality of wires 6 and may receive power voltage required for operations from the package substrate 8 through others (e.g., other portions) of the plurality of wires 6.

The plurality of wire bonding pads 5 may be disposed (e.g., arranged) on an upper surface of the memory device 4 in the first direction. The memory device 4 may include a plurality of signal redistribution patterns and a plurality of power redistribution patterns, and the plurality of wire bonding pads 5 may be respectively connected to a signal redistribution pattern among the plurality of signal redistribution patterns or a power redistribution pattern among the plurality of power redistribution patterns. The plurality of signal redistribution patterns may connect some (e.g., portions) of the plurality of wire bonding pads 5 to a plurality of signal via pads.

The plurality of signal redistribution patterns included in the memory device 4 may be disposed on one side with respect to the plurality of wire bonding pads 5, and the plurality of power redistribution patterns may be disposed on the other side with respect to the plurality of wire bonding pads 5. In this case, the plurality of signal redistribution patterns and the plurality of power redistribution patterns may be disposed in different positions based on (with respect to) the plurality of wire bonding pads 5, in a second direction (e.g., Y-axis direction in FIG. 1) intersecting the first direction. The first direction and the second direction are parallel to the upper surface of the package substrate 8. The first direction and the second direction may intersect each other. The first direction and the second direction may be perpendicular to each other. For example, the plurality of wire bonding pads 5 may be between the plurality of signal redistribution patterns and the plurality of power redistribution patterns in the second direction.

By disposing the plurality of signal redistribution patterns on the one side with respect to the plurality of wire bonding pads 5 in the second direction, respective lengths of the plurality of signal redistribution patterns may be shortened and signal integrity may be improved. In addition, by disposing the plurality of power redistribution patterns on the other side with respect to the plurality of wire bonding pads 5, the respective widths of the plurality of power redistribution patterns may be increased without interference of the plurality of signal redistribution patterns, and therefore, power integrity may also be improved. As used herein, the direction of “width” of an element A may be perpendicular to the direction of “length” of the element A. For example, the direction of “length” of the element A may refer to a lengthy (e.g., elongated) direction of the element A, and the direction of “width” of the element A may refer to a direction perpendicular to the lengthy (e.g., elongated) direction of the element A.

FIG. 2 is a diagram illustrating a semiconductor package according to some example embodiments.

Referring to FIG. 2, a semiconductor package 10 according to some example embodiments may include a plurality of memory devices 14, a molding portion 17, a package substrate 18, and the like. The plurality of memory devices 14 may be stacked in a third direction perpendicular to an upper surface of the package substrate 18 (e.g., Z-axis direction in FIG. 2) by a plurality of adhesive layers 13. For example, the plurality of memory devices 14 and the plurality of adhesive layers 13 may be alternately stacked on the upper surface of the package substrate 18 in the third direction. In the example embodiment illustrated in FIG. 2, three memory devices 14 are illustrated as being stacked, but the number of memory devices 14 included in the semiconductor package 10 may be variously modified according to some example embodiments. The molding portion 17 may be formed on (e.g., may cover) the plurality of memory devices 14 and (e.g., the upper surface of) the package substrate 18.

The package substrate 18 may include a plurality of connection pads 12, and the plurality of connection pads 12 may be disposed (e.g., arranged) in the first direction (e.g., X-axis direction in FIG. 2). In some embodiments, the plurality of connection pads 12 may be disposed on the upper surface of the package substrate 18. The plurality of connection pads 12 may be respectively connected to a plurality of wire bonding pads 15 formed on the plurality of memory devices 14 by a plurality of wires 16. Accordingly, the plurality of memory devices 14 may transmit and receive signals to and from the package substrate 18 through some (e.g., portions) of the plurality of wires 16, and may receive power supply voltage required for operations from the package substrate 18 through others (e.g., other portions) of the plurality of wires 16.

The plurality of wire bonding pads 15 may be disposed on upper surfaces of the plurality of respective memory devices 14 and arranged in the first direction. The plurality of memory devices 14 may include a plurality of signal redistribution patterns and a plurality of power redistribution patterns. The plurality of wire bonding pads 15 may respectively be connected to a signal redistribution pattern among the plurality of signal redistribution patterns or a power redistribution pattern among the plurality of power redistribution patterns. The plurality of signal redistribution patterns may connect some of the plurality of wire bonding pads 15 to a plurality of signal via pads.

The plurality of signal redistribution patterns included in the plurality of memory devices 14 may be disposed on one side with respect to the plurality of wire bonding pads 15, and the plurality of power redistribution patterns may be disposed on the other side with respect to the plurality of wire bonding pads 15. In this case, based on (with respect to) the plurality of wire bonding pads 15, the one side may correspond to a direction parallel to the upper surface of the package substrate 18 and toward the plurality of wires 16, and the other side may correspond to a direction parallel to the upper surface of the package substrate 18 and away from the plurality of wires 16. For example, the plurality of wires 16 may be closer to the one side than the other side in a direction parallel to the upper surface of the package substrate 18 (e.g., the second direction). In some embodiments, the plurality of wire bonding pads 15 may be between the plurality of signal redistribution patterns and the plurality of power redistribution patterns in the second direction.

By disposing the plurality of signal redistribution patterns on the one side with respect to the plurality of wire bonding pads 15 in the second direction, a length of each of a plurality of signal redistribution patterns may be shortened and signal integrity may be improved. In addition, by disposing the plurality of power redistribution patterns on the other side with respect to the plurality of wire bonding pads 15, a width of each of the plurality of power redistribution patterns may be increased without interference of the plurality of signal redistribution patterns, and power integrity may also be improved.

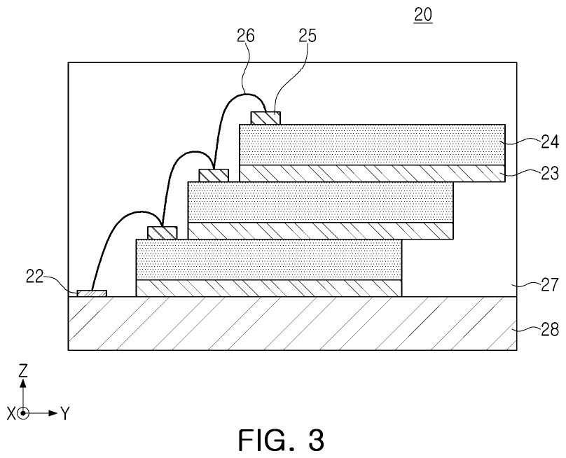

FIG. 3 is a diagram illustrating a semiconductor package according to some example embodiments.

Referring to FIG. 3, a semiconductor package 20 according to some example embodiments may include a plurality of memory devices 24, a molding portion 27, and a package substrate 28. The plurality of memory devices 24 may be stacked in the third direction (e.g., Z-axis direction in FIG. 3). For example, the plurality of memory device 24 may be alternately stacked with a plurality of adhesive layers 23 on an upper surface of the package substrate 28. In the example embodiment illustrated in FIG. 3, three memory devices 24 are illustrated as being stacked, but the number of memory devices 24 included in the semiconductor package 20 may be variously modified according to some example embodiments. The molding portion 27 may be formed on (e.g., to cover) the plurality of memory devices 24 and (e.g., the upper surface of) the package substrate 28.

The package substrate 28 may include a plurality of connection pads 22, and the plurality of connection pads 22 may be disposed (arranged) in the first direction (e.g., X-axis direction in FIG. 3). In some embodiments, the plurality of connection pads 22 may be disposed on the upper surface of the package substrate 28. The plurality of connection pads 22 may be connected to a plurality of wire bonding pads 25 formed on the plurality of memory devices 24 by a plurality of wires 26. Accordingly, the plurality of memory devices 24 may respectively transmit and receive signals to and from the package substrate 28 through some (e.g., portions) of the plurality of wires 26 and may receive power supply voltage required for operation from the package substrate 28 through others (e.g., other portions) of the plurality of wires 26.

The plurality of connection pads 22 may be connected to some wire bonding pads 25 among the plurality of wire bonding pads 25 on a lowermost memory device 24 among the plurality of memory devices 24 through some wires 26 among the plurality of wires 26. Some wire bonding pads 25 on the plurality of memory devices 24 other than the lowermost memory device 24 may be connected to other wire bonding pads 25 on the adjacent memory devices 24 through some wires 26 among the plurality of wires 26, respectively.

The plurality of wire bonding pads 25 may be disposed (e.g., arranged) on upper surfaces of the plurality of respective memory devices 24 in the first direction. Each of the plurality of memory devices 24 may include a signal redistribution pattern and a power redistribution pattern, and each of the plurality of wire bonding pads 25 may be connected to the signal redistribution pattern or the power redistribution pattern. A plurality of signal redistribution patterns may connect some (e.g., portions) of the plurality of wire bonding pads 25 to a plurality of signal via pads.

The plurality of signal redistribution patterns included in the plurality of memory devices 24 may be disposed on one side with respect to the plurality of wire bonding pads 25, and a plurality of power redistribution patterns may be disposed on the other side with respect to the plurality of wire bonding pads 25. In this case, based on (with respect to) the plurality of wire bonding pads 25, the one side may be parallel to the upper surface of the package substrate 28 and correspond to a direction toward the plurality of wires 26, and the other side may correspond to a direction parallel to the upper surface of the package substrate 28 and away from the plurality of wires 26. For example, the plurality of wire bonding pads 25 may be between the plurality of signal redistribution patterns and the plurality of power redistribution patterns in the second direction.

By disposing the plurality of signal redistribution patterns on the one side with respect to the plurality of wire bonding pads 25 in the second direction, a length of each of the plurality of signal redistribution patterns may be shortened and signal integrity may be improved. In addition, by disposing the plurality of power redistribution patterns on the other side with respect to the plurality of wire bonding pads 25, the width of each of the plurality of power redistribution patterns may be increased without interference of the plurality of signal redistribution patterns, and thus, power integrity may also be improved.

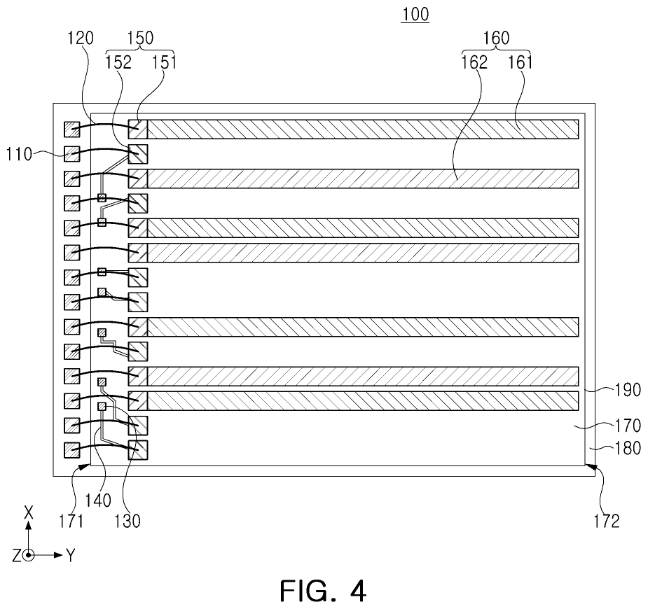

FIG. 4 is a plan view illustrating a semiconductor package according to some example embodiments.

FIG. 4 may be a view illustrating a semiconductor package 100 viewed from above an upper surface of the semiconductor package 100. The semiconductor package 100 may include a plurality of connection pads 110, a plurality of wires 120, a package substrate 180, a memory device 190, and the like.

The memory device 190 may include a plurality of signal via pads 130, a plurality of signal redistribution patterns 140, a plurality of wire bonding pads 150, a plurality of power redistribution patterns 160, a semiconductor body 170, and the like. The semiconductor body 170 may include a semiconductor substrate comprising a semiconductor material, a plurality of semiconductor elements formed on the semiconductor substrate, a plurality of wiring patterns connecting the plurality of semiconductor elements to each other, an interlayer insulating layer formed on the semiconductor substrate to be disposed on (e.g., to cover) the plurality of semiconductor elements and the plurality of wiring patterns, and the like.

The plurality of wire bonding pads 150 may be disposed in the first direction (e.g., X-axis direction in FIG. 4). The semiconductor body 170 may have a first edge 171 and a second edge 172 that extend in the first direction and are parallel to each other, and the first edge 171 may overlap (e.g., cross) the plurality of wires 120. It will be understood that when an element A is referred to as entirely overlapping an element B, at least a surface of the element A may be entirely covered by the element B.

The plurality of wire bonding pads 150 may include a plurality of power wire bonding pads 151 connected to the plurality of power redistribution patterns 160, and a plurality of signal wire bonding pads 152 connected to the plurality of signal redistribution patterns 140. A distance between the plurality of wire bonding pads 150 and the first edge 171 in the second direction (e.g., Y-axis direction in FIG. 4) may be less (e.g., shorter) than a distance between the plurality of wire bonding pads 150 and the second edge 172 in the second direction (e.g., Y-axis direction in FIG. 4). In detail, the plurality of wire bonding pads 150 may be disposed adjacent to the first edge 171 that is close (e.g., closer than the second edge 172) to the plurality of connection pads 110 in the second direction (e.g., Y-axis direction in FIG. 4) so that the lengths of the plurality of wires 120 are not excessively long.

The plurality of power wire bonding pads 151 and the plurality of signal wire bonding pads 152 may be alternately disposed or disposed in an arbitrary order. In an example embodiment, the plurality of wire bonding pads 150 may be disposed in a line in the first direction (e.g., X-axis direction in FIG. 4). For example, the plurality of power wire bonding pads 151 and the plurality of signal wire bonding pads 152 may overlap each other in the first direction. For example, as illustrated in FIG. 4, a distance between the first edge 171 and each of the plurality of wire bonding pads 150 in the second direction (e.g., Y-axis direction in FIG. 4) may be substantially the same.

Referring to FIG. 4, the plurality of signal via pads 130 may be disposed between the plurality of wire bonding pads 150 and the first edge 171 in the second direction. Similar to the plurality of wire bonding pads 150, the plurality of signal via pads 130 may be disposed in the first direction.

The distance between the pads positioned at both (e.g., opposing) ends of the plurality of wire bonding pads 150 in the first direction may be greater than the distance between the pads positioned at both (e.g., opposing) ends of the plurality of signal via pads 130 in the first direction. The size of each of the plurality of signal via pads 130 may be less (e.g., smaller) than the size of each of the plurality of wire bonding pads 150.

The plurality of signal via pads 130 may be connected to the plurality of signal wire bonding pads 152 by the plurality of signal redistribution patterns 140. On the other hand, the plurality of power wire bonding pads 151 may be connected to the plurality of power redistribution patterns 160 extending in the second direction.

Referring to FIG. 4, each of the plurality of signal redistribution patterns 140 may include one straight line pattern or may include two or more straight line patterns bent one or more times and extending in different directions. A width of each of the plurality of signal redistribution patterns 140 may be less (e.g., thinner) than a width of each of the plurality of power redistribution patterns 160. On the other hand, a length of each of the plurality of signal redistribution patterns 140 may be less (e.g., shorter) than a length of each of the power redistribution patterns 160. The plurality of signal redistribution patterns 140 may be disposed at the same height (e.g., distance) from the upper surface of the semiconductor substrate included in the semiconductor body 170 in the third direction (e.g., Z-axis direction in FIG. 4).

The plurality of power redistribution patterns 160 may include a plurality of power voltage redistribution patterns 161 for distributing the power voltage and a plurality of ground voltage redistribution patterns 162 for distributing the ground voltage. As in the example embodiment illustrated in FIG. 4, the plurality of power voltage redistribution patterns 161 and the plurality of ground voltage redistribution patterns 162 may be alternately disposed or disposed in an arbitrary order. At least some (e.g., portions) of the plurality of power redistribution patterns 160 may be connected to power patterns among wiring patterns included in the semiconductor body 170.

Each of the plurality of power redistribution patterns 160 may have a rectangular shape in a plan view. In the example embodiment illustrated in FIG. 4, the plurality of power redistribution patterns 160 may respectively have the same length in the second direction, and the plurality of power redistribution patterns 160 may be respectively disposed parallel to the second direction. For example, each of the plurality of power redistribution patterns 160 may extend in the second direction. The plurality of power redistribution patterns 160 may be disposed at the same height (e.g., distance) from the upper surface of the semiconductor body 170 in the third direction (e.g., Z-axis direction in FIG. 4).

One end of each of the plurality of wires 120 may be connected to the plurality of connection pads 110 formed on the package substrate 180, and the other end thereof may be connected to the plurality of wire bonding pads 150. The plurality of wires 120 may extend to overlap (e.g., cross) the first edge 171 of the semiconductor body 170, and at least one of the plurality of wires 120 may have an overlapping area with at least one of the plurality of signal redistribution patterns 140 in the third direction (Z-axis direction in FIG. 4).

The plurality of signal redistribution patterns 140 may be disposed on the side of (e.g., adjacent to) the first edge 171 with respect to the plurality of wire bonding pads 150 included in the semiconductor body 170, and the plurality of power redistribution patterns 160 may be disposed on the side of (e.g., adjacent to) the second edge 172 with respect to the plurality of wire bonding pads 150, and thus, the plurality of signal redistribution patterns 140 and the plurality of power redistribution patterns 160 may not be adjacent to each other. As a result, the length of the plurality of signal redistribution patterns 140 may be reduced, and the capacitance value and resistance value of the plurality of signal redistribution patterns 140 may be effectively reduced. Therefore, the integrity of a signal transmitted to the plurality of signal redistribution patterns 140 may be improved.

In addition, by forming the plurality of power redistribution patterns 160 to extend toward the second edge 172, a sufficient space in which the plurality of power redistribution patterns 160 are to be disposed may be secured. Therefore, the width of the plurality of power redistribution patterns 160 may be increased compared to the case in which the plurality of signal redistribution patterns 140 and the plurality of power redistribution patterns 160 are extended in the same direction, and the integrity of the power voltage transmitted to the plurality of power redistribution patterns 160 may be improved.

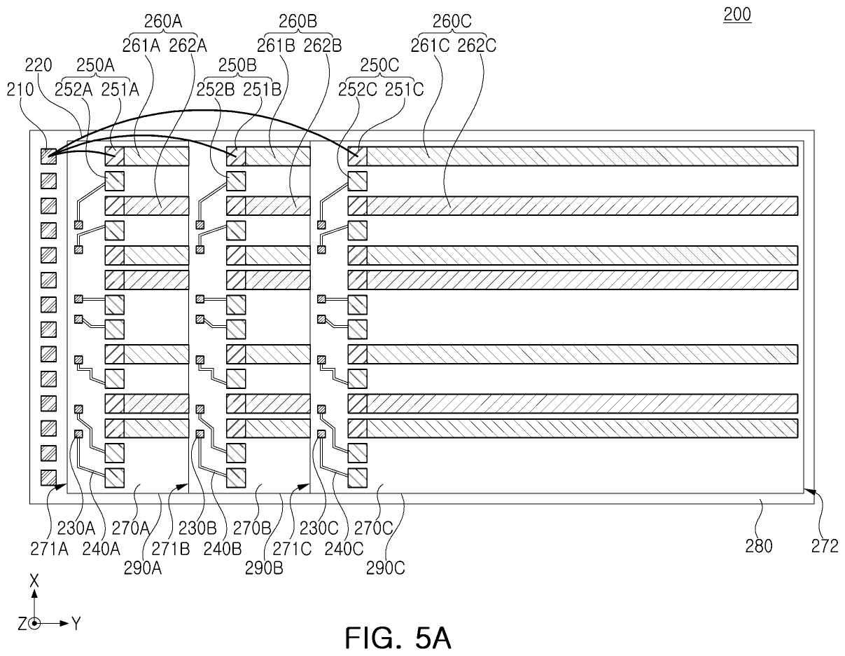

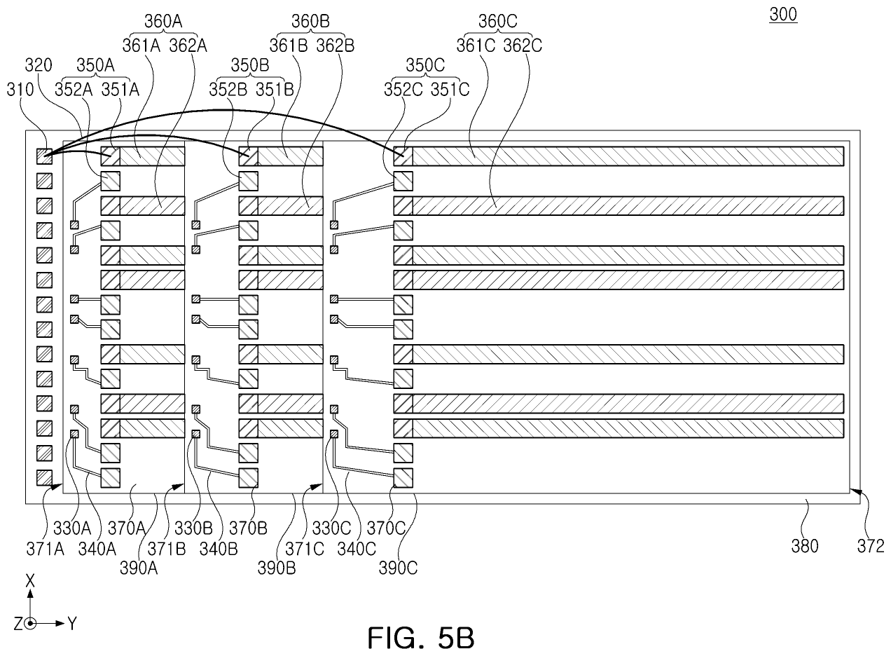

FIGS. 5A and 5B are plan views illustrating a semiconductor package according to some example embodiments.

Referring first to FIG. 5A, FIG. 5A may be a plan view illustrating the semiconductor package 200 viewed from above an upper surface of the semiconductor package 200. The semiconductor package 200 may include a plurality of connection pads 210, a plurality of wires 220, a package substrate 280, a plurality of memory devices 290A, 290B, and 290C.

The plurality of memory devices 290A, 290B, and 290C may be stacked in the third direction. The third direction may be perpendicular to an upper surface of the package substrate 280 (e.g., Z-axis direction in FIG. 5A). In the example embodiment illustrated in FIG. 5A, three memory devices 290A, 290B, and 290C are stacked, but the number of memory devices 290A, 290B, and 290C included in the semiconductor package 200 may be variously modified according to example embodiments.

The plurality of memory devices 290A, 290B, and 290C may respectively include a plurality of signal via pads 230A, 230B, and 230C, a plurality of signal redistribution patterns 240A, 240B and 240C, a plurality of wire bonding pads 250A, 250B, and 250C, a plurality of power redistribution patterns 260A, 260B and 260C, semiconductor bodies 270A, 270B and 270C, and the like. The semiconductor bodies 270A, 270B, and 270C may include a semiconductor substrate including a semiconductor material, a plurality of semiconductor elements formed on a semiconductor substrate, a plurality of wiring patterns connecting the plurality of semiconductor elements to each other, an interlayer insulating layer formed on the semiconductor substrate to be disposed on (e.g., to cover) the plurality of semiconductor elements and the plurality of wiring patterns, and the like.

The plurality of wire bonding pads 250A, 250B, and 250C may be disposed (e.g., arranged) in the first direction (e.g., X-axis direction in FIG. 5A) parallel to the upper surfaces of the semiconductor bodies 270A, 270B, and 270C. The semiconductor bodies 270A, 270B, and 270C may respectively have first edges 271A, 271B, and 271C and a second edge 272 that extend in the first direction and are parallel to each other, and the first edges 271A, 271B, and 271C may overlap (e.g., cross) the plurality of wires 220.

The plurality of wire bonding pads 250A, 250B, and 250C may respectively include a plurality of power wire bonding pads 251A, 251B, and 251C respectively connected to the plurality of power redistribution patterns 260A, 260B, and 260C and a plurality of signal wire bonding pads 252A, 252B, and 252C respectively connected to the plurality of signal redistribution patterns 240A, 240B, and 240C. The respective distances between the plurality of wire bonding pads 250A, 250B, and 250C and the first edge 271A, 271B, 271C in the second direction may be less (e.g., shorter) than the respective distances between the plurality of wire bonding pads 250A, 250B, and 250C and the second edge 272 in the second direction. In detail, the plurality of wire bonding pads 250A, 250B, and 250C may be disposed adjacent to the first edges 271A, 271B, and 271C, respectively, that are close (e.g., closer than the second edge 272) to the plurality of connection pads 210, to prevent the length of the plurality of wires 220 from being excessively long.

The respective plurality of power wire bonding pads 251A, 251B, and 251C and the respective plurality of signal wire bonding pads 252A, 252B, and 252C may be alternately disposed or disposed in an arbitrary order. In an example embodiment, each of the plurality of wire bonding pads 250A, 250B, and 250C may be disposed in a line in the first direction. For example, the plurality of power wire bonding pads 251A, 251B, and 251C and the plurality of signal wire bonding pads 252A, 252B, and 252C may respectively overlap each other in the first direction. For example, as illustrated in FIG. 5A, distances between the respective first edges 271A, 271B, and 271C and the respective plurality of wire bonding pads 250A, 250B, and 250C may be substantially the same in the second direction (e.g., Y-axis direction in FIG. 5A).

Referring to FIG. 5A, in the plurality of respective memory devices 290A, 290B, and 290C, the plurality of signal via pads 230A, 230B, and 230C may be disposed between the plurality of wire bonding pads 250A, 250B, and 250C and the first edges 271A, 271B, and 271C in the second direction, respectively. In the plurality of respective memory devices 290A, 290B, and 290C, the plurality of signal via pads 230A, 230B, and 230C may be disposed (e.g., arranged) in the first direction, similarly to the plurality of wire bonding pads 250A, 250B, and 250C, respectively.

The distance between pads located on both (e.g., opposing) ends in the first direction among the plurality of wire bonding pads 250A, 250B, and 250C may be greater than the distance between pads located on both (e.g., opposing) ends in the first direction among the plurality of signal via pads 230A, 230B, and 230C, respectively. The size of each of the plurality of signal via pads 230A, 230B, and 230C may be smaller than each of the plurality of wire bonding pads 250A, 250B, and 250C, respectively.

The plurality of signal via pads 230A, 230B, and 230C may be respectively connected to the plurality of signal wire bonding pads 252A, 252B, and 252C by the plurality of signal redistribution patterns 240A, 240B, and 240C, respectively. On the other hand, the plurality of power wire bonding pads 251A, 251B, and 251C may be respectively connected to the plurality of power redistribution patterns 260A, 260B, and 260C extending in the second direction.

Referring to FIG. 5A, each of the plurality of signal redistribution patterns 240A, 240B, and 240C may include one straight line pattern, or may include two or more straight line patterns bent one or more times and extending in different directions. Widths of the plurality of signal redistribution patterns 240A, 240B, and 240C may be less (e.g., thinner) than widths of the plurality of power redistribution patterns 260A, 260B, and 260C, respectively. Each of the plurality of signal redistribution patterns 240A, 240B, and 240C may have a length less (e.g., shorter) than a length of each of the power redistribution patterns 260A, 260B, and 260C, respectively. The plurality of signal redistribution patterns 240A, 240B, and 240C may be disposed at the same height (e.g., distance in the third direction) from the upper surfaces of the semiconductor substrates included in the semiconductor bodies 270A, 270B, and 270C, respectively.

The plurality of power redistribution patterns 260A, 260B, and 260C may respectively include a plurality of power voltage redistribution patterns 261A, 261B, and 261C for distributing the power voltage, and a plurality of ground voltage redistribution patterns 262A, 262B, and 262C for distributing the ground voltage. As in the example embodiment illustrated in FIG. 5A, the respective plurality of power voltage redistribution patterns 261A, 261B, and 261C and the respective plurality of ground voltage redistribution patterns 262A, 262B, and 262C may be alternately disposed or disposed in an arbitrary order. At least some (e.g., portions) of the plurality of power redistribution patterns 260A, 260B, and 260C may be connected to the power pattern among wiring patterns included in the semiconductor bodies 270A, 270B, and 270C, respectively.

Each of the plurality of power redistribution patterns 260A, 260B, and 260C may have a rectangular shape in a plan view. In the example embodiment illustrated in FIG. 5A, the plurality of power redistribution patterns 260A, 260B, and 260C may respectively have the same length in the second direction, and the plurality of power redistribution patterns 260A, 260B and 260C may be respectively disposed parallel to the second direction. The plurality of power redistribution patterns 260A, 260B, and 260C may be disposed at the same height (e.g., the same distance in the third direction) from the upper surfaces of the semiconductor bodies 270A, 270B, and 270C, respectively.

Respective one ends of the plurality of wires 220 may be connected to a plurality of connection pads 210 formed on the package substrate 280, and the other ends thereof may be respectively connected to the plurality of wire bonding pads 250A, 250B, and 250C. The plurality of wires 220 may extend to overlap (e.g., cross) the first edges 271A, 271B, and 271C of the semiconductor bodies 270A, 270B, and 270C, respectively, and at least one of the plurality of wires 220 may have an overlapping area with at least one of the plurality of signal redistribution patterns 240A, 240B, and 240C in the third direction (e.g., Z-axis direction in FIG. 5A). Unlike the illustration in the drawings, actual wires (the plurality of wires 220) may be connected to each of the plurality of connection pads 210.

In some embodiments, the plurality of wires 220 may be similarly connected as described in FIG. 3. The plurality of connection pads 210 may be connected to a plurality of wire bonding pads 250A of the lowermost memory device 290A by some of the plurality of wires 220, respectively. The plurality of wire bonding pads 250B and 250C of the remaining memory devices 290B and 290C may be connected to the plurality of wire bonding pads 250A, 250B, and 250C of adjacent memory devices 290A, 290B, and 290C by others of the plurality of wires 220, respectively.

Based on (e.g., with respect to) the plurality of wire bonding pads 250A, 250B, and 250C included in the semiconductor bodies 270A, 270B, and 270C, the plurality of signal redistribution patterns 240A, 240B, and 240C may be disposed on the side of (e.g., adjacent to) the first edges 271A, 271B, and 271C, respectively, and the plurality of power redistribution patterns 260A, 260B, and 260C may be disposed on the side of (e.g., adjacent to) the second edge 272, respectively, and thus, the plurality of signal redistribution patterns 240A, 240B, and 240C and the plurality of power redistribution patterns 260A, 260B, and 260C may not be adjacent to each other. For example, the plurality of wire bonding pads 250A, 250B, and 250C may be between the plurality of signal redistribution patterns 240A, 240B, and 240C and the plurality of power redistribution patterns 260A, 260B, and 260C, respectively. As a result, the length of the plurality of signal redistribution patterns 240A, 240B, and 240C may be reduced, and the inherent capacitance and resistance values of the plurality of signal redistribution patterns 240A, 240B, and 240C may be effectively reduced, thereby improving the integrity of signals transmitted to the plurality of signal redistribution patterns 240A, 240B, and 240C.

In addition, by forming the plurality of power redistribution patterns 260A, 260B, and 260C to extend toward the second edge 272, a sufficient space in which the plurality of power redistribution patterns 260A, 260B, and 260C are to be disposed may be secured. Therefore, compared to the case in which the plurality of signal redistribution patterns 240A, 240B, and 240C and the plurality of power redistribution patterns 260A, 260B, and 260C are extended in the same direction, the width of the plurality of power redistribution patterns 260A, 260B, and 260C may be increased, and the integrity of the power voltage transmitted to the plurality of power redistribution patterns 260A, 260B, and 260C may be improved.

Referring to FIG. 5B, FIG. 5B may be a plan view illustrating a semiconductor package 300 viewed from above an upper surface of the semiconductor package 300. The semiconductor package 300 may include a plurality of connection pads 310, a plurality of wires 320, a package substrate 380, a plurality of memory devices 390A, 390B and 390C, and the like, and detailed embodiments thereof may be similar to those described in FIG. 5A.

Referring to FIG. 5A, the distances in the second direction between the plurality of wire bonding pads 250A, 250B, and 250C and the first edges 271A, 271B, and 271C in the plurality of memory devices 290A, 290B, and 290C may be equal to each other, respectively.

On the other hand, referring to FIG. 5B, the distance in the second direction between some of the plurality of wire bonding pads and the respective first edge in the respective memory device located in a relatively higher position in the stacking direction (e.g., the third direction or Z-axis direction of FIG. 5B) may be greater than the distance in the second direction between others of the plurality of wire bonding pads and the respective first edge in the respective memory device located in a relatively lower position in the stacking direction (e.g., the third direction or Z-axis direction of FIG. 5B).

In detail, the distance in the second direction between a first edge 371B and a plurality of wire bonding pads 350B in a memory device 390B located in the middle position in the stacking direction (e.g., the third direction or Z-axis direction in FIG. 5B) may be greater than the distance in the second direction between a first edge 371A and a plurality of wire bonding pads 350A in a memory device 390A located in the lower position in the stacking direction (e.g., the third direction or Z-axis direction of FIG. 5B). On the other hand, the distance in the second direction between a first edge 371C and a plurality of wire bonding pads 350C in a memory device 390C located in the higher position in the stacking direction (e.g., the third direction or Z-axis direction of FIG. 5B) may be greater than the distance between the first edge 371B and the plurality of wire bonding pads 350B in the memory device 390B located in the middle position in the stacking direction (e.g., the third direction or Z-axis direction of FIG. 5B).

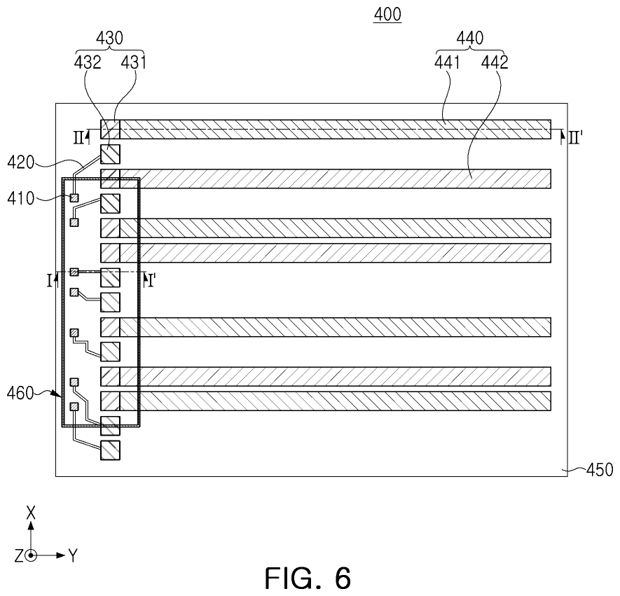

FIG. 6 is a plan view illustrating a memory device according to some example embodiments.

FIG. 6 may be a plan view illustrating a memory device 400 viewed from above an upper surface of the memory device 400. The memory device 400 may include a semiconductor substrate including a semiconductor material, a plurality of semiconductor elements formed on the semiconductor substrate, a plurality of wiring patterns connecting the plurality of semiconductor elements to each other, an interlayer insulating layer formed on the semiconductor substrate to be disposed on (e.g., cover) the plurality of semiconductor elements and the plurality of wiring patterns, and the like.

The memory device 400 may include a plurality of signal via pads 410, a plurality of signal redistribution patterns 420, a plurality of wire bonding pads 430, a plurality of power redistribution patterns 440, a semiconductor body 450, and the like.

The plurality of wire bonding pads 430 may include a plurality of power wire bonding pads 431 connected to the plurality of power redistribution patterns 440 and a plurality of signal wire bonding pads 432 connected to the plurality of signal redistribution patterns 420. The plurality of power redistribution patterns 440 may include a plurality of power voltage redistribution patterns 441 and a plurality of ground voltage redistribution patterns 442.

In the example embodiment illustrated in FIG. 6, a first region 460 may be referred to as an input/output circuit area of the memory device 400. A driver circuit outputting a signal, a receiver circuit receiving a signal, and the like may be disposed in the input/output circuit area. The plurality of signal via pads 410 may be respectively connected to an output terminal of the driver circuit and/or an input terminal of the receiver circuit. For example, a pad for inputting/outputting a data signal among the plurality of signal via pads 410 may be connected to the output terminal of the driver circuit and the input terminal of the receiver circuit in common.

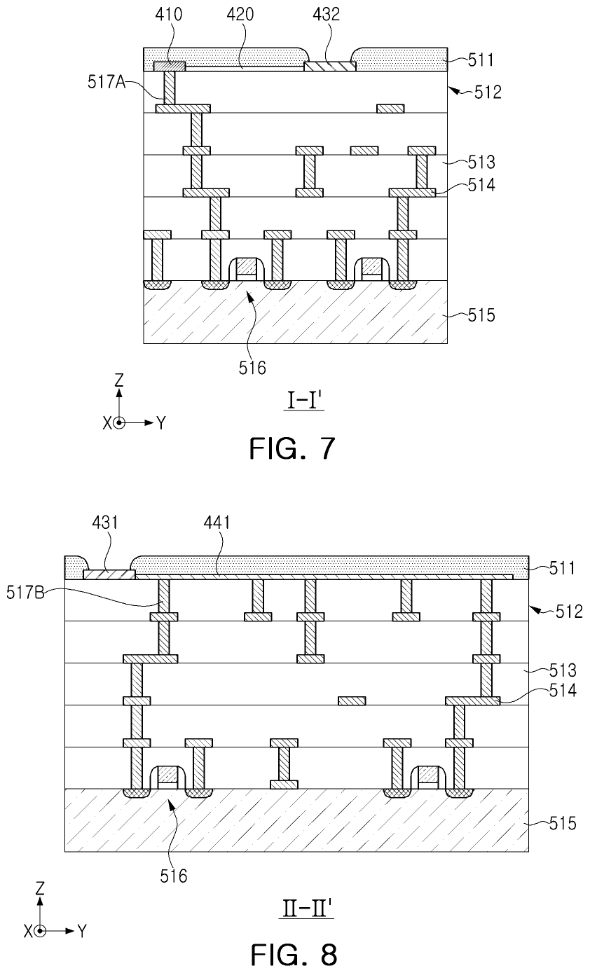

FIG. 7 is a cross-sectional view of the memory device according to the example embodiments illustrated in FIG. 6, in the direction I-I′.

The cross section in the direction I-I′ may correspond to the cross section of the first region 460 of the memory device 400 described with reference to FIG. 6. Referring to FIG. 7, a passivation layer 511 may be formed on an upper portion of the memory device 400, and a signal wire bonding pad 432 may be externally exposed in a region in which the passivation layer 511 has been removed. As used hereinafter, the terms “external/outside configuration”, “external/outside device”, “external/outside power”, “external/outside signal”, “external”, or “outside” are intended to broadly refer to a device, circuit, block, module, power, and/or signal that resides externally (e.g., outside of a functional or physical boundary) with respect to a given circuit, block, module, system, or device. A signal via pad 410, a signal redistribution pattern 420, and the signal wire bonding pad 432 may be positioned on a redistribution layer 512. The signal redistribution pattern 420 may be connected to (e.g., may contact) the signal wire bonding pad 432 and the signal via pad 410 to connect the signal wire bonding pad 432 and the signal via pad 410 to each other. It will be understood that when an element A is referred to as exposing another element B, while the element A may be on the element B, the element A may not entirely cover the element B and at least a portion of the element B may not be covered by the element A.

The signal via pad 410 may be connected to lower wiring patterns 514 through an upper contact 517A. The lower wiring patterns 514 may be wiring patterns connecting semiconductor elements 516 formed on a semiconductor substrate 515 to the redistribution layer 512. A plurality of interlayer insulating layers 513 may be disposed on (e.g., cover) the lower wiring patterns 514 and the semiconductor elements 516.

In the example embodiment illustrated in FIG. 7, the semiconductor elements 516 connected to the signal via pad 410 through the lower wiring patterns 514 and the upper contact 517A may be semiconductor elements comprising an input/output circuit. For example, the semiconductor elements 516 connected to the signal via pad 410 may be semiconductor elements that comprise a driver circuit or a receiver circuit in an input/output circuit.

FIG. 8 is a cross-sectional view of the memory device according to the example embodiments illustrated in FIG. 6, in a direction II-II′.

Similar to the above description with reference to FIG. 7, the passivation layer 511 may be formed on the upper portion of the memory device 400, and the power wire bonding pad 431 may be exposed externally in a partial area in which the passivation layer 511 has been removed. A power wire bonding pad 431 and a power voltage redistribution pattern 441 may be positioned on the redistribution layer 512. In detail, the power wire bonding pad 431 and the power voltage redistribution pattern 441 may be disposed on the redistribution layer 512 along with the signal via pad 410, the signal redistribution pattern 420, and the signal wire bonding pad 432. The power voltage redistribution pattern 441 may be connected to (e.g., may contact) the power wire bonding pad 431 and the upper contact 517B and may connect the power wire bonding pad 431 and the upper contact 517B to each other.

Semiconductor elements 516 may be formed on a semiconductor substrate 515. The semiconductor elements 516 may be connected to lower wiring patterns 514, and the lower wiring patterns 514 may be at least partially covered with a plurality of interlayer insulating layers 513.

As an example, the semiconductor elements 516 illustrated in FIG. 8 may be different from the semiconductor elements that comprise the input/output circuit as described with reference to FIG. 7. In an example embodiment, the semiconductor elements 516 illustrated in FIG. 8 may be elements comprising a core circuit included in the memory device 400 and may comprise circuits such as a row decoder, a sense amplifier, a page buffer, a voltage generator, and the like. In some embodiments, the semiconductor elements 516 may comprise at least portions of memory cells.

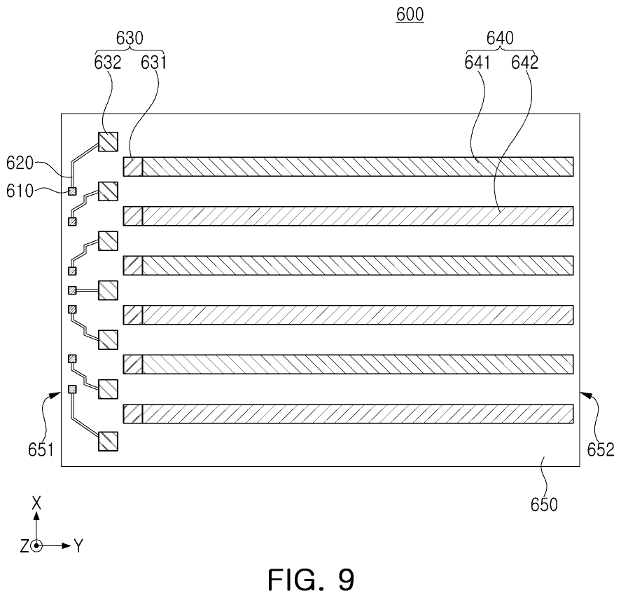

FIG. 9 is a plan view illustrating a memory device according to some example embodiments.

Referring to FIG. 9, a memory device 600 according to some example embodiments may include a plurality of signal via pads 610, a plurality of signal redistribution patterns 620, a plurality of wire bonding pads 630, a plurality of power redistribution patterns 640, a semiconductor body 650, and the like.

The plurality of wire bonding pads 630 may be disposed (e.g., arranged) in the first direction (e.g., X-axis direction in FIG. 9). The semiconductor body 650 may have a first edge 651 and a second edge 652 that extend in the first direction and are parallel to each other. The plurality of power redistribution patterns 640 may include a plurality of power voltage redistribution patterns 641 and a plurality of ground voltage redistribution patterns 642.

The plurality of wire bonding pads 630 may include a plurality of power wire bonding pads 631 respectively connected to the plurality of power redistribution patterns 640, and a plurality of signal wire bonding pads 632 respectively connected to the plurality of signal redistribution patterns 620. A distance between the plurality of wire bonding pads 630 and the first edge 651 in the second direction (e.g., Y-axis direction in FIG. 9) may be less (e.g., shorter) than a distance between the plurality of wire bonding pads 630 and the second edge 652 in the second direction. For example, the plurality of wire bonding pads 630 may be disposed between the first edge 651 and the second edge 652. In detail, the plurality of wire bonding pads 630 may be disposed closer to the first edge 651 than to the second edge 652.

Some (e.g., Portions) of the plurality of wire bonding pads 630 may be disposed (e.g., arranged) in the first direction at a first position in the second direction. On the other hand, others (e.g., remaining portions) of the plurality of wire bonding pads 630 may be disposed (e.g., arranged) in the first direction at a second position, different from the first position in the second direction. The first position may be disposed between the first edge 651 of the semiconductor body 650 and the second position in the second direction. In detail, the first position may be closer to the first edge 651 than the second position in the second direction.

In this case, the plurality of signal wire bonding pads 632 may be disposed in the first position, and the plurality of power wire bonding pads 631 may be disposed in the second position. Accordingly, the plurality of signal wire bonding pads 632 may be disposed between the plurality of signal via pads 610 and the plurality of power wire bonding pads 631 in the second direction.

Compared to the arrangement of the plurality of wire bonding pads 150 illustrated in FIG. 4, the plurality of signal wire bonding pads 632 according to the example embodiments of FIG. 9 may be disposed to be relatively close to the plurality of signal via pads 610. For example, since the length of the plurality of signal redistribution patterns 620 may be designed to be relatively shorter (e.g., minimal), signal integrity may be effectively improved.

Also, unlike the example embodiments of FIG. 4, the plurality of power wire bonding pads 631 according to the example embodiments of FIG. 9 may be disposed separately from the plurality of signal wire bonding pads 632. For example, the plurality of power wire bonding pads 631 and the plurality of signal wire bonding pads 632 may not overlap each other in the first direction, but the embodiments of the present inventive concepts are not limited thereto. In detail, the plurality of power wire bonding pads 631 may not be interfered with by the plurality of signal wire bonding pads 632. For example, since the size of the plurality of power wire bonding pads 631 and the width of the plurality of power redistribution patterns 640 may be sufficiently increased, power integrity may be effectively improved.

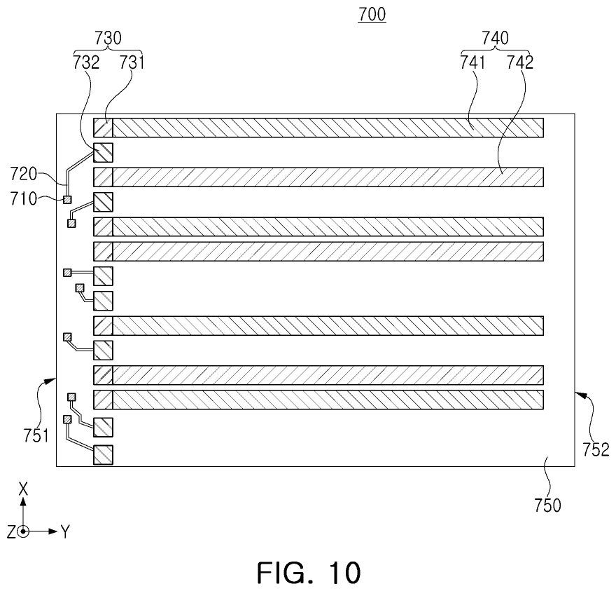

FIG. 10 is a plan view illustrating a memory device according to some example embodiments.

Referring to FIG. 10, a memory device 700 according to some example embodiments may include a plurality of signal via pads 710, a plurality of signal redistribution patterns 720, a plurality of wire bonding pads 730, a plurality of power redistribution patterns 740, a semiconductor body 750, and the like.

The plurality of wire bonding pads 730 may be disposed in a line in the first direction (e.g., X-axis direction in FIG. 10). The semiconductor body 750 may have a first edge 751 and a second edge 752 extending in the first direction and parallel to each other. The plurality of power redistribution patterns 740 may include a plurality of power voltage redistribution patterns 741 and a plurality of ground voltage redistribution patterns 742.

The plurality of wire bonding pads 730 may include a plurality of power wire bonding pads 731 respectively connected to the plurality of power redistribution patterns 740, and a plurality of signal wire bonding pads 732 respectively connected to the plurality of signal redistribution patterns 720.

The plurality of signal via pads 710 may be disposed between the plurality of wire bonding pads 730 and the first edge 751. Some of the plurality of signal via pads 710 may have different distances from the first edge 751 each other in the second direction (e.g., Y-axis direction in FIG. 10). For example, the plurality of signal via pads 710 may have more than one distance from the first edge 751 in the second direction.

Therefore, the positions of the plurality of signal via pads 710 may be determined, such that the plurality of signal redistribution patterns 720 may respectively have a minimum length. Therefore, signal integrity may be efficiently improved.

In the second direction, the plurality of signal redistribution patterns 720 may be disposed on one side with respect to the plurality of wire bonding pads 730, and the plurality of power redistribution patterns 740 may be disposed on the other side with respect to the plurality of wire bonding pads 730.

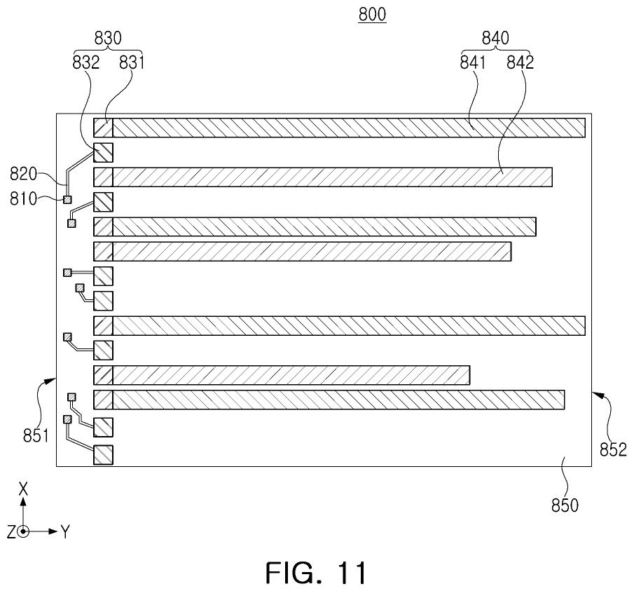

FIG. 11 is a plan view illustrating a memory device according to some example embodiments.

Referring to FIG. 11, a memory device 800 according to some example embodiments may include a plurality of signal via pads 810, a plurality of signal redistribution patterns 820, a plurality of wire bonding pads 830, a plurality of power redistribution patterns 840, a semiconductor body 850, and the like.

The plurality of wire bonding pads 830 may be disposed (e.g., arranged) in the first direction (e.g., X-axis direction in FIG. 11). The semiconductor body 850 may have a first edge 851 and a second edge 852 that extend in the first direction and are parallel to each other. The plurality of power redistribution patterns 840 may include a plurality of power voltage redistribution patterns 841 and a plurality of ground voltage redistribution patterns 842.

The plurality of wire bonding pads 830 may include a plurality of power wire bonding pads 831 respectively connected to the plurality of power redistribution patterns 840 and a plurality of signal wire bonding pads 832 respectively connected to the plurality of signal redistribution patterns 820.

The plurality of signal via pads 810 may be disposed between the plurality of wire bonding pads 830 and the first edge 851 in the second direction. Some of the plurality of signal via pads 810 may have different distances from the first edge 851 each other in the second direction (e.g., Y-axis direction in FIG. 11). For example, the plurality of signal via pads 810 may have more than one distance from the first edge 851 in the second direction.

In the second direction, the plurality of signal redistribution patterns 820 may be disposed on one side with respect to the plurality of wire bonding pads 830, and the plurality of power redistribution patterns 840 may be disposed on the other side with respect to the plurality of wire bonding pads 830. For example, the plurality of wire bonding pads 830 may be between the plurality of signal redistribution patterns 820 and the plurality of power redistribution patterns 840 in the second direction.

Each of the plurality of power redistribution patterns 840 may have a rectangular shape in a plan view. Also, the plurality of power redistribution patterns 840 may be disposed at the same height (e.g., distance in the third direction) from the upper surface of the semiconductor body 850. Also, in the example embodiment of FIG. 11, the plurality of power redistribution patterns 840 may have different lengths in the second direction. For example, the plurality of power redistribution patterns 840 may have more than one length in the second direction. Therefore, efficient design of the power redistribution pattern 840 may be possible.

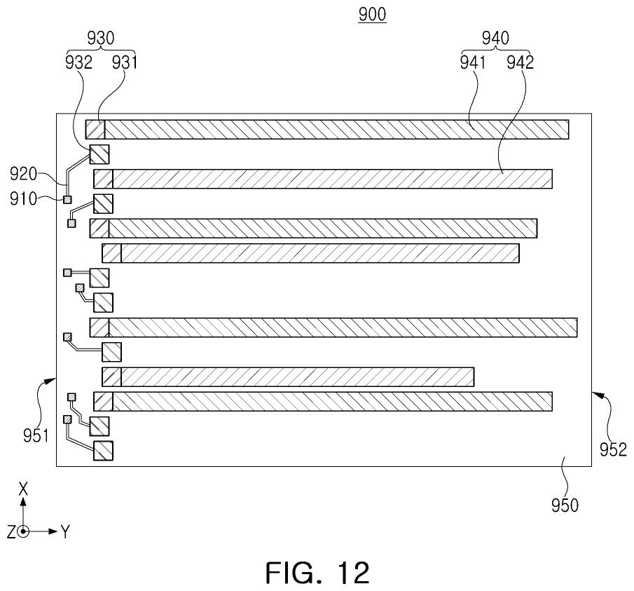

FIG. 12 is a plan view illustrating a memory device according to some example embodiments.

Referring to FIG. 12, a memory device 900 according to some example embodiments may include a plurality of signal via pads 910, a plurality of signal redistribution patterns 920, a plurality of wire bonding pads 930, a plurality of power redistribution patterns 940, a semiconductor body 950, and the like.

The semiconductor body 950 may have a first edge 951 and a second edge 952 parallel to each other. The first edge 951 and the second edge 952 may extend in the first direction (e.g., X-axis direction in FIG. 12). The plurality of power redistribution patterns 940 may include a plurality of power voltage redistribution patterns 941 and a plurality of ground voltage redistribution patterns 942. The plurality of wire bonding pads 930 may include a plurality of power wire bonding pads 931 respectively connected to the plurality of power redistribution patterns 940, and a plurality of signal wire bonding pads 932 respectively connected to the plurality of signal redistribution patterns 920.

Some of the plurality of wire bonding pads 930 may have different distances from the first edge 951 in the second direction to each other. For example, the plurality of wire bonding pads 930 may have more than one distance from the first edge 951 in the second direction. For example, the plurality of wire bonding pads 930 may not be arranged in a line extending in the first direction. However, the plurality of wire bonding pads 930 may overlap each other in the first direction. Accordingly, the positions of the plurality of wire bonding pads 930 may be designed such that the plurality of signal redistribution patterns 920 may have a reduced (e.g., minimum) length, thereby efficiently improving signal integrity.

The plurality of signal via pads 910 may be disposed between the plurality of wire bonding pads 930 and the first edge 951. The plurality of signal via pads 910 may have different distances from the first edge 951 to each other in the second direction. For example, the plurality of signal via pads 910 may include more than one distance from the first edge 951 in the second direction.

The plurality of power redistribution patterns 940 may be respectively connected to the plurality of power wire bonding pads 931. The plurality of power redistribution patterns 940 may have a rectangular shape in a plan view, may have different lengths in the second direction, and may be disposed parallel to the second direction to maintain a straight shape. The plurality of power redistribution patterns 940 may be disposed at the same height (e.g., distance) from the upper surface of the semiconductor body 950 in the third direction.

The example embodiments of FIGS. 4 to 5B and 9 to 12 may be applied crosswise.

For example, in the example embodiment illustrated in FIG. 5B, the plurality of wire bonding pads 350A, 350B, and 350C may be disposed as in the example embodiment illustrated in FIG. 12. In detail, distances between at least portions of the plurality of wire bonding pads 350A, 350B, and 350C and the first edges 371A, 371B, and 371C may be different from each other as illustrated in FIG. 12.

In addition, in the example embodiment illustrated in FIG. 9, at least portions of the plurality of power redistribution patterns 640 may have different lengths in the second direction (e.g., Y-axis direction in FIG. 9) as illustrated in FIG. 11.

In addition, in the example embodiment illustrated in FIG. 10, the distances between at least portions of the plurality of wire bonding pads 730 and the first edge 751 may be different as illustrated in FIG. 12.

In addition, in the example embodiment illustrated in FIG. 11, a plurality of signal via pads 810 may be disposed (e.g., arranged) in a line in the first direction (e.g., X-axis direction in FIG. 11) as illustrated in FIG. 9.

On the other hand, in the example embodiment illustrated in FIG. 12, the plurality of signal via pads 910 may be disposed (e.g., arranged) in a line in the first direction (X-axis direction in FIG. 12) as illustrated in FIG. 9.

In the example embodiment illustrated in FIG. 12, the plurality of wire bonding pads 930 may be disposed as in the example embodiment of FIG. 9. For example, portions of the plurality of wire bonding pads 930 may be disposed (e.g., arranged) in the first direction at a first position in the second direction (Y-axis direction in FIG. 12), and the remaining portions may be disposed (e.g., arranged) in the first direction at a second position in the second direction, different from the first position. In this case, the plurality of signal wire bonding pads 932 may be disposed at the first position, and the plurality of power wire bonding pads 931 may be disposed at the second position.

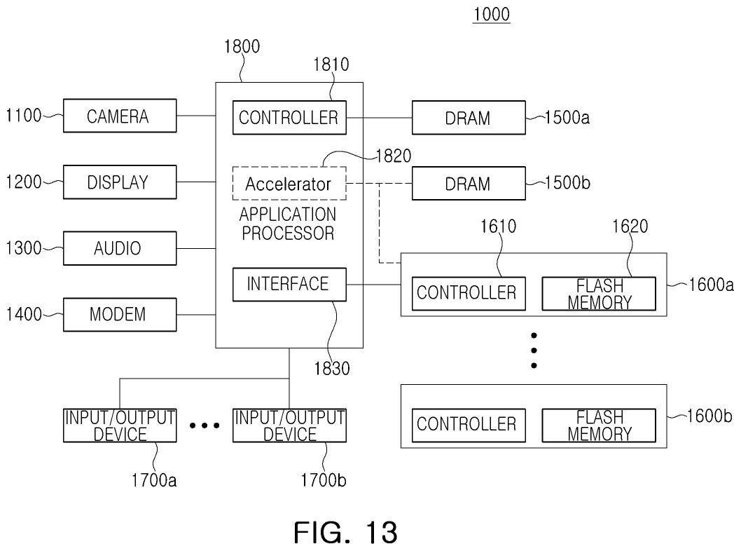

FIG. 13 is a simplified block diagram of a mobile system including a memory device according to some example embodiments.

Referring to FIG. 13, a mobile system 1000 may include a camera 1100, a display 1200, an audio processor 1300, a modem 1400, DRAMs 1500a and 1500b, flash memory devices 1600a and 1600b, input/output devices 1700a and 1700b, and an application processor (hereinafter, referred to as “AP”) 1800. However, the embodiments of the present inventive concept are not limited thereto.

The mobile system 1000 may be implemented as a laptop computer, a portable terminal, a smart phone, a tablet PC, a wearable device, a healthcare device, or an Internet-of-Things (IoT) device. Also, the mobile system 1000 may be implemented as a server or a personal computer. However, the embodiments of the present inventive concept are not limited thereto.

According to example embodiments, the mobile system 1000 may include a plurality of DRAMs 1500a and 1500b or a plurality of flash memory devices 1600a and 1600b. Although only DRAMs 1500a and 1500b are illustrated in FIG. 12, the configuration of the mobile system 1000 is not necessarily limited to this form, and depending on the bandwidth, response speed, and voltage conditions of the AP 1800 or an accelerator block 1820, other memories may also be included in the mobile system 1000 other than the DRAMs 1500a and 1500b.

In the example embodiment illustrated in FIG. 13, the DRAMs 1500a and 1500b and the flash memory devices 1600a and 1600b may be memory devices according to the example embodiments described above with reference to FIGS. 1 to 12.

As set forth above, according to an example embodiment, the signal redistribution patterns included in the memory device may be disposed on one side of the wire bonding pads, and power redistribution patterns may be disposed on the other side of the wire bonding pads. Accordingly, even when input/output circuits are concentrated in a predetermined area, signal integrity may be improved by significantly reducing an increase in the length of signal redistribution patterns. In addition, by forming power redistribution patterns to have a sufficient width, the integrity of power may also be improved.

While example embodiments have been illustrated and described above, it will be apparent to those skilled in the art that modifications and variations could be made without departing from the scope of the present inventive concept as defined by the appended claims.

What is claimed is:

1. A memory device comprising:
a semiconductor substrate;
a plurality of wire bonding pads on the semiconductor substrate and arranged in a first direction;
a plurality of signal redistribution patterns connecting first wire bonding pads among the plurality of wire bonding pads to a plurality of signal via pads, respectively, wherein the plurality of signal redistribution patterns are on a first side with respect to the plurality of wire bonding pads in a second direction that is perpendicular to the first direction; and
a plurality of power redistribution patterns connected to second wire bonding pads among the plurality of wire bonding pads, respectively, wherein the plurality of power redistribution patterns are on a second side with respect to the plurality of wire bonding pads in the second direction,
wherein the first and second directions are parallel with an upper surface of the semiconductor substrate.

2. The memory device of claim 1, wherein the first wire bonding pads among the plurality of wire bonding pads are arranged in the first direction, at a first position in the second direction,
the second wire bonding pads among the plurality of wire bonding pads are arranged in the first direction, at a second position,
the second position is different from the first position in the second direction, and
the first wire bonding pads among the plurality of wire bonding pads are between the plurality of signal via pads and the second wire bonding pads among the plurality of wire bonding pads in the second direction.

3. The memory device of claim 2, wherein the first wire bonding pads among the plurality of wire bonding pads are connected to the plurality of signal redistribution patterns, and
the second wire bonding pads among the plurality of wire bonding pads are connected to the plurality of power redistribution patterns.

4. The memory device of claim 1, wherein the semiconductor substrate has a first edge and a second edge extending in the first direction,
the plurality of wire bonding pads have different distances from the first edge in the second direction.

5. The memory device of claim 4, wherein a width of each of the plurality of signal redistribution patterns is thinner than a width of each of the plurality of power redistribution patterns.

6. The memory device of claim 5, wherein a length of each of the plurality of signal redistribution patterns is shorter than a length of each of the plurality of power redistribution patterns.

7. The memory device of claim 6, wherein a distance between pads positioned on opposing ends in the first direction among the plurality of wire bonding pads is greater than a distance between pads positioned on opposing ends in the first direction among the plurality of signal via pads.

8. The memory device of claim 7, wherein the plurality of signal redistribution patterns are at a same distance from the upper surface of the semiconductor substrate in a third direction that is perpendicular to the upper surface of the semiconductor substrate.

9. The memory device of claim 8, wherein the plurality of signal via pads are arranged in the first direction.

10. The memory device of claim 9, wherein each of the plurality of power redistribution patterns extends in the second direction.

11. The memory device of claim 10, wherein the plurality of power redistribution patterns respectively have a same length in the second direction.

12. The memory device of claim 10, wherein the plurality of power redistribution patterns have different lengths in the second direction.

13. The memory device of claim 12, wherein the plurality of power redistribution patterns are at a same distance from the upper surface of the semiconductor substrate in the third direction.

14. A memory device comprising:
a semiconductor substrate having a first edge and a second edge that are parallel to each other, wherein the first edge and the second edge extend in a first direction that is parallel to an upper surface of the semiconductor substrate;
a plurality of wire bonding pads on the semiconductor substrate and arranged in the first direction; and
a plurality of signal via pads between the first edge and the plurality of wire bonding pads,
wherein a distance between the plurality of wire bonding pads and the first edge is shorter than a distance between the plurality of wire bonding pads and the second edge.

15. The memory device of claim 14, wherein first wire bonding pads among the plurality of wire bonding pads are arranged in the first direction, at a first position,
second wire bonding pads among the plurality of wire bonding pads are arranged in the first direction, at a second position, wherein the first position and the second position are at different positions in a second direction that is perpendicular to the first direction and parallel to the upper surface of the semiconductor substrate, and
the first wire bonding pads among the plurality of wire bonding pads are between the plurality of signal via pads and the second wire bonding pads among the plurality of wire bonding pads in the second direction.

16. The memory device of claim 15, wherein the first wire bonding pads among the plurality of wire bonding pads are connected to a plurality of signal redistribution patterns, respectively, and
the second wire bonding pads among the plurality of wire bonding pads are connected to a plurality of power redistribution patterns, respectively.

17. A semiconductor package comprising:
a memory device;
a package substrate positioned below the memory device; and
a plurality of wires connecting the memory device and the package substrate,
wherein the memory device includes:
a semiconductor substrate;
a plurality of wire bonding pads on the semiconductor substrate and arranged in a first direction that is parallel to an upper surface of the semiconductor substrate;
a plurality of signal redistribution patterns connecting first wire bonding pads among the plurality of wire bonding pads to a plurality of signal via pads, wherein the plurality of signal redistribution patterns are on one side with respect to the plurality of wire bonding pads in a second direction that is perpendicular to the first direction and parallel to the upper surface of the semiconductor substrate; and
a plurality of power redistribution patterns connected to second wire bonding pads among the plurality of wire bonding pads, wherein the plurality of power redistribution patterns are on the other side with respect to the plurality of wire bonding pads in the second direction, and
the plurality of wires are connected to the plurality of wire bonding pads, wherein at least one of the plurality of wires overlaps at least one of the plurality of signal redistribution patterns.

18. The semiconductor package of claim 17, wherein the memory device is a first memory device,
the semiconductor package further comprising:
memory devices, including the first memory device, stacked in a third direction that is perpendicular to the upper surface of the semiconductor substrate,
wherein the plurality of wire bonding pads are on the memory devices, and
wherein the plurality of wires are connected to the plurality of wire bonding pads, respectively.

19. The semiconductor package of claim 18, wherein each of the semiconductor substrates of the memory devices has a first edge and a second edge extending in the first direction, and each of the first edges overlaps the plurality of wires,
a distance between upper wire bonding pads among the plurality of wire bonding pads of an upper memory device among the memory devices and a first edge of the upper memory device in the second direction is greater than a distance between lower wire bonding pads among the plurality of wire bonding pads of a lower memory device among the memory devices and a first edge of the lower memory device in the second direction.

20. The semiconductor package of claim 19, wherein the plurality of wire bonding pads have different distances from the first edges, respectively, in the second direction.
